(19) United States
(12) Patent Application Publication
(10) Pub. No.: US 2010/0062184 A1
(43) Pub. Date: Mar. 11, 2010

(54) Method and Apparatus for the Surface Modification of Flat Substrates

(76) Inventors: Konrad Kaltenbach, Furtwangen (DE); Frank Schienle, Freiburg (DE); Andreas Baldus, Bollschweil (DE); Ghassan Barbar, Wildtal (DE)

Correspondence Address: BIOTECH BEACH LAW GROUP , PC, 5677 OBERLINE DRIVE, SUITE 204, SAN DIEGO, CA, 92121, US

(21) Appl. No.: 12/525,262

(22) PCT Filed: May 20, 2008
(86) PCT No.: PCT/EP08/04053

§ 371 Date: Jul. 30, 2009

(30) Foreign Application Priority Data
May 25, 2007 (DE) 10 2007 024 667.8

(51) Int. Cl. B05D 3/06; B05D 1/18; B05D 5/12; B05C 3/00

(52) U.S. Cl. 427/581; 427/430.1; 427/74; 118/429

(57) ABSTRACT

The invention in general relates to the single-sided wet chemical surface modification as in particular the coating of flat substrates. In particular, the present invention relates to a method as well as to an apparatus for the coating of substrates in the course of the production of thin film solar cells or modules made from glass, metal, or plastic with metallic compounds such as i.e. cadmium sulphide or zinc sulphide.

The invention in general relates to the single-sided wet chemical modification of substrate surfaces, and, more precisely, to the single-sided wet chemical coating of flat substrates. In particular, the present invention relates to a method as well as to an apparatus for the coating of substrates in the course of the production of thin film solar cells or modules made from glass, metal, or plastic with metallic compounds such as i.e. cadmium sulphide or zinc sulphide.

For the coating of flat surfaces, a multitude of most different methods and apparatuses is known in the art, whose selection primarily depends on the type and thickness of the desired coating as well as on the composition or structure of the substrate to be coated. For instance, it can be differentiated between current-mediated and current-free precipitation, as well as between vapor and liquid deposition, as also between high- and low-temperature processes. In particular in the production of solar cells, mostly several coatings of the carrier structures or substrates such as i.e. glass plates take place in order to provide the cells with the necessary stability as well as with the desired characteristics. A particularly promising method uses so-called CIS-layers which stand out by a high light absorption. For this, firstly the back contact, mostly from molybdenum (Mo) with a layer thickness between 0.5 and 1 μm, and subsequently a 1-2 μm thin layer of copper-indium-sulphide, copper-indium-diselenide, copper-gallium-sulphide, or copper-gallium-diselenide (generally referred to as CI(G)S(Se)), are applied single-sided onto a substrate, before this accordingly modified side of the substrate in a subsequent step is coated with a so-called sulphidic buffer layer such as with i.e. cadmium sulphide (CdS) or zinc sulphide (ZnS). As starting material, usually cadmium or zinc containing compounds and salts are used such as i.e. cadmium or zinc sulphate or acetate, respectively, as well as thiourea (THS, CH₄N₂S) and ammoniac (NH₄OH), which are separately stored, and only mixed in the desired relation shortly before the coating. The thin CdS- or ZnS-layer resulting from the coating and generally having a thickness between 30 and 90 nm, and in particular between 30 and 60 nm, should firmly stick to the previously deposited CI(G)S(Se)-layer and be as far as possible homogenous with regard to its structure, thickness, and composition, in order to achieve an optimal efficiency. The substrates to be coated typically have dimensions of 1,200 mm in length and of 600 mm in width as well as a thickness of 3 mm, whereas the entirety of the coatings only has a thickness ranging from the nanometer- to the micrometer region. In the future, however even larger substrate areas are desired due to reasons of cost optimization.

It is known that an effective deposition (precipitation) of CdS or ZnS onto the surface of a substrate can take place only within a certain temperature range which lies between approximately room temperature or 30° C., respectively, and approximately 95° C. Upon application of wet chemical coating techniques using a treatment basin, care must therefore be taken that the temperature of the liquid in the bath is properly controlled both as a whole as well as in the region contacting the surface to be treated, so that the minimal temperature of approx. 20° to 30° C. that is necessary trigger the desired deposition is reached, however, without allowing the temperature in the liquid bath to rise in such a manner that the undesired reactions described in the art (i.e. formation of colloids) take place which put the coating result at risk and entail an increased consumption of liquid as well as possibly the necessity of subsequent treatment steps as e.g. such for cleaning. In order to tackle this problem, the state of the art has developed alternatives in which e.g. the substrate side to be coated is no more transferred into a coating bath, but manually or automatically wetted with the liquid. In order to generate a most possible uniform, reaction-supporting temperature, the substrate is e.g. transferred with the lower side that is not to be coated into an accordingly tempered water bath and placed onto the surface of the same. After the substrate is sufficiently heated up to its surface to be treated, the liquid composition that comprises the chemical components is applied from above onto the substrate surface, so that the formation of the desired layer is induced.

Therefore, particularly such devices are known from the art in which a liquid composition that causes the desired coating of the substrate is applied single-sided from above onto the carrier structures.

However, such devices suffer from a number of drawbacks. For example, it is often not desired that besides the upper side, also the edges of the substrates are wetted with the treatment liquid. For this, appropriately complex or precise application techniques are necessary in order to avoid a lateral flow down of the treatment liquid. For this purpose, circumferential sealing rings are usually used that must also ensure that the treatment liquid does not enter and thus contaminates the water bath. Further, the upper side with the applied liquid must be shielded against the environment in order to rule out contaminations of the substrate as well as a hazard for the user. The exact dosing of the treatment liquid must also be reproducibly ensured at any time, since this would otherwise result in different layer thicknesses and/or in differently developed and thus inhomogeneous layers, by what the functional characteristics such as e.g. the efficiency of the later processed product can be affected. Possible excessive amounts of treatment liquid must be drained off and reconditioned or disposed. In addition, only a relatively slow temperature rise takes place when using a water bath for the heating, since the temperature of the water must significantly lie below 100° C. due to the otherwise increasing formation of bubbles and steam, therefore limiting the amount of heat supply. Furthermore, the substrate side that is wetted by the water of the water bath must be dried again after the treatment, requiring an additional treatment step and containing the risk of a deposition of undesired matter due to drying. Finally, such devices produce in a so-called “batch mode”, i.e. non-continuously in a batch method, which limits the throughput and is undesired particularly regarding high and highest quantities. In particular, also a high mechanical and fluidic handling effort results from this non-continuous treatment, leading to accordingly high costs and an increase of processing time.

Object of the present invention is therefore the provision of a method and an apparatus for the single-sided wet chemical surface modification as in particular the coating of flat substrates, by which the problems according to the state of the art are overcome. According to the invention, the method as well as the apparatus shall ensure a maximum of homogeneity and be applicable on flat substrates in a continuous manner, i.e. in the course of an “inline”-processing, without the side that is not to be treated being wetted during the treatment duration with a heating liquid. Further, the method shall allow for a single-sided surface modification or coating, without the substrate being held from above, e.g. by a vacuum chuck, or protected from being wetted by the treatment liquid.

For solution of the object, the method according to the main claim as well as the apparatus according to the claim 12 are provided. Preferred embodiments are subject-matter of the respective subclaims, the subsequent description, as well as the FIGURE.

The invention relates to a method for the single-sided wet chemical surface modification as in e.g. the single-sided wet chemical coating of an essentially flat substrate, as e.g. a glass, metal, and/or plastic plate or foil, respectively, by using a liquid being present in a treatment basin, whose chemical components are precipitable (depositable) by suitable temperature control onto the substrate surface under formation of a permanent layer. According to the invention, the heating of the substrate lower side to be coated which is necessary for the formation of the desired layer is not effected by the treatment liquid, but by at least one suitable means that is preferably located outside of the liquid or the treatment basin and capable of heating the substrate to the necessary temperature. According to the invention, it is provided that the upper side that is not to be treated is not wetted during treatment with a heating liquid, so that it neither comes into contact with the treatment liquid, nor with another heating liquid for thermal transfer. Since according to the invention preferably even any wetting of the side that is not to be treated does not occur, also a resulting necessity for subsequent removal of the liquid or for drying the substrate surface not to be treated respectively does not apply. According to the invention, it is further provided that during treatment the substrate is neither held nor protected from above, so that the substrate merely rests on at least one suitable support of the apparatus according to the invention, and that it can be done without the usage of a holder such as e.g. a vacuum chuck.

According to the invention, a modification or coating of the lower side including the circumferential substrate edge can be carried out, if desired.

It is particularly preferred that the method according to the invention is performed in the course of the production of thin film solar cells or modules, made from glass, metal, and/or plastic, wherein the preferably aqueous treatment liquid comprises cadmium or zinc sulphate or acetate, respectively, as well as a sulphur source such as e.g. thiourea (THS, CH₄N₂S), and a nitrogen source such as e.g. ammoniac (NH₄OH). Mostly preferred, a treatment liquid is used in which the concentrations of the reactants amount to approx. 0.1 mol/l cadmium or zinc sulphate, max. 1 mol/l THS, and approx. 16 mol/l ammoniac. Such treatment liquids are known in the art and can be easily provided by anyone skilled in the art.

The method, however, is neither limited to this treatment liquid, nor to this application. Besides the coating of solid plate material, the method according to the invention can also be used for the coating of flexible roll or foil material as e.g. of polyimide or stainless steel foils. Besides the above mentioned materials, also layer formations of the same with each other as well as with other element or compound semiconductors that are common in photovoltaics come into consideration, such as e.g. Si, Ge, CdTe, or also conducting polymers. For example, the method according to the invention can also be used in the production of organic luminescence diodes (OLEDs).

It is clear to the one skilled in the art that the present invention is suitable both for the current-free as well as for the current-mediated coating of flat substrates of the mentioned type, although the current-free coating is presently preferred.

In order to achieve a coating with a most possible high and constant quality, the composition and/or the temperature of the treatment liquid according to a preferred embodiment of the method are continuously monitored and readjusted if required.

Depending on the application, accordingly suitable means as e.g. sensors are used for the monitoring of the composition of the treatment liquid, which particularly preferred are coupled to a control device. If applicable, this control device regulates the feed-in of the reactants into the treatment liquid. Alternatively or additionally, samples for the determination of the respective mixing ratios and/or concentrations of the reactants can be taken from the liquid, preferably at certain times of the treatment duration, or also between the subsequent treatment of several substrates, thus enabling a readjustment according to the results.

For the monitoring of the desired temperature range of the treatment liquid, such as particularly for the maintenance of the maximum temperature provided for the purpose of application, also accordingly suitable means such as e.g. sensors can be used, wherein it is again particularly preferred that these are coupled to a further control device by which e.g. the valves of a reservoir tank with cooled treatment liquid can be controlled.

According to another preferred embodiment the substrate during treatment with its lower side that is to be treated rests on a suitable transport means and is continuously transported over or through the liquid. Particularly preferred, the transport takes place such that exclusively the lower-side of the substrate comes into contact with the treatment liquid. According to this embodiment, the method can be used in the course of a continuous “inline”-production for the treatment of lager quantities with comparatively short cycle times.

According to another preferred embodiment of the method, several means for heating the substrate are used, whose thermal transfer to the substrate or whose power can be controlled independently from each other. This control can be effected by simple on/off switching of the respective means, by controlling the amount of heat or power that exerts onto the substrate, and/or by introducing suitable orifices or filters into the ray path.

In the case of a static treatment without or with motionless transport means, the lower side of the substrate during it's coating is preferably uniformly heated to different temperatures, whereby a particularly good coating result can be achieved. According to the invention it could be demonstrated that the coating of a substrate fulfils even highest quality demands, when different temperatures exert on it's under-side during treatment duration, which is particularly true when the substrate lower side is exposed to relatively low temperatures at the beginning of the treatment, and to relatively higher temperatures in the further course of the same. Compared with a constantly high reaction temperature, one gets in this manner a finer and more homogenous deposition at the substrate surface to be coated. In the case of a treatment with continuous transport of the substrate the means for heating are preferably controlled independently of each other such that the substrate lower side to be coated is differently heated during its transport over or through the liquid, and therefore undergoes or experiences in transport direction a predetermined temperature profile. In this manner, the respective power of the means for heating can also be adjusted such that, when viewed in transport direction of the treatment basin, it transfers or induces differently high heat quantities to or in the substrate at respectively different locations of the basin, so that e.g. reduced heat power is present at the beginning of the bath, and full heat power is present at the middle region of the bath. In doing so, the aforementioned effect resulting from the action of different temperatures on the substrate lower side can also be achieved with continuous processing. Contrary to apparatuses known in the art, with which the passage through a temperature profile during heating up is only—if at all—possible in a very limited way, and then only can be achieved with accordingly long reaction times, a rapid and also locally well controllable heat transfer to or heat induction in the substrate respectively takes place according to the invention.

In the case of a continuous transport of the substrate it is particularly preferred that the control of the means for heating is effected in such a manner that, in a substrate's cutting plane which is perpendicular to the transport direction, the aforementioned temperature profile is almost constant over the entire width of the substrate, and in particular, in the region of its lower-side to be coated. Advantageously, the temperature deviation in the region of the substrate lower side should be ±1% or less.

Instead of a direct control of the means for heating, these can at any time emit a constant amount of heat which, however, can be reduced by further means such as orifices or filters and/or concentrated by mirrors or lenses such that the desired heat distribution is achieved at the surface of the substrate to be coated.

According to another embodiment, the at least one means for heating of the substrate is selected from the group consisting of thermal radiators, thermal transfer devices, thermal inductors, and combinations thereof. While thermal radiators do not directly contact the substrate and the heat is transferred to the substrate via radiation exclusively, and preferably in the long-wave infrared region, thermal transfer devices, which, besides solids, also comprise gases such as e.g. hot air, are in direct physical contact to the upper side that is not to be treated, where they transmit the heat in the form of heat transfer to the substrate. Finally, thermal inductors do not provide the heat itself, but deliver, e.g. via radiation, an amount of energy which is then transformed into heat energy inside the substrate or at its surface, for which according absorbers must be comprised by the substrate.

Although, these thermal inductors thus do not provide any heat as such, they entirely belong to the group of means for heating according to the invention, since they also cause the desired heating of the substrate side to be modified or coated. Therefore, the present general and preferred explanations regarding the number, position and control of the at least one means for heating explicitly are also valid for the thermal inductors. According to the invention the thermal radiators and the thermal inductors as well as combinations thereof are preferred, since only these means offer the possibility to achieve a selective heating of the substrate's lower side straight through the substrate body, and particularly if the radiation is absorbed at a suitable absorber which is located at the lower side of the substrate that is to be treated, and if it passes the rest of the substrate body almost unhindered.

Regarding thermal radiators, this e.g. applies to glass substrates that are single-sided coated with metal, as they are used in the solar cell production. If, in the case of an at least partially transparent substrate, such cells or modules also comprise a reflecting and/or absorbing as e.g. a metallic layer which is arranged between the substrate and the sulphidic as e.g. CdS- or ZnS-layer to be generated, an absorption of the heat radiation which is irradiated from the side that is not to be treated and at least partially penetrates the substrate body is effected by the reflecting and/or absorbing layer itself. At the same time, this layer is heated, so that the heat is provided just where it is needed, namely directly at the substrate lower side that is to be treated. At the same time, this layer prevents penetration of the heat irradiation into the treatment liquid, what is particularly preferred according to the invention, since otherwise the heat induced reaction process within the liquid could also take place at another location than directly at the substrate surface. In the case of a substrate material which is not transparent for the heat irradiation, the use of site-specific absorption does therefore not apply; here, the substrate must be heated as a whole.

Preferably, the at least one thermal radiator is therefore selected from the group consisting of long-wave infrared radiators, infrared lasers, and microwave devices.

The at least one thermal transfer device is preferably selected from the group consisting of heatable plates, cylinders, rollers, bands, mats, and foils.

As already mentioned before, the heat which is necessary for the deposition can according to the invention also be generated or provided by means of induction such as e.g. electromagnetic induction. Electromagnetic induction means the formation of an electrical voltage along a conducting loop due to a change of the magnetic flux, e.g. due to application of a preferably low-frequency alternating current field. This flux change can be induced by a change of position or shape of the conducting loop within the magnetic field, and/or by a change of the strength or the orientation of the magnetic field. Due to the induced voltage, a current flows which results in the desired heating of the conducting loop (inductive heating by eddy current). The conducting loop that is comprised by the substrate to be modified can according to the invention have a one or two part design and has an arbitrary shape; it can as well be an integral or surface-resting component of the substrate. In this manner, the thermal inductors can be used for the modification or coating according to the invention of pure metallic substrates as well as of substrates whose surfaces are either fully or partly, and particularly stripe- or dot-shaped covered with conductive materials.

Thermal inductors offer similar advantages as thermal radiators, wherein upon presence of a metallic substrate (e.g. a metal plate or foil), a volume heating takes place, whereas upon mere presence of a metallic layer on the otherwise non-conducting substrate, this metallic layer is exclusively heated. In particular in the second case, neither a heating of the remaining substrate material, nor of the treatment liquid takes place, if one leaves aside the secondary heating resulting from the metallic layer contacting the remainder of the substrate and the treatment fluid. However, the latter is very low due to the very efficient heat generation. Furthermore, the generation of the heat by means of induction has a number of further advantages. The amount of heat to be supplied can be dosed very precise, the heat is supplied particularly rapid and with a higher efficiency, and embedded layers can be heated as well, as long as the surrounding material is transparent for the induction irradiation.

The at least one thermal inductor is preferably selected from the group consisting of electromagnetic induction coils and electromagnetic inductors.

According to a further aspect of the present invention, an apparatus for carrying out the method according to the invention is provided.

The apparatus according to the invention for the single-sided wet chemical surface modification as in particular the coating of an essentially flat substrate comprises at least one treatment basin for reception of treatment liquid, at least one suitable means for heating the substrate lower side to be coated to the temperature that is necessary for the formation of the desired layer, as well as at least one means for supporting and positioning the substrate with its side to be treated facing downwards, wherein the apparatus does not comprise any means by which the substrate can be held from above or protected. The at least one means for heating is preferably selected from the group consisting of thermal radiators, thermal transfer devices, thermal inductors, and combinations of the same, whereby it is particularly preferred that the at least one thermal radiator is selected from the group consisting of long-wave infrared radiators, infrared lasers, and microwave devices, whereas the at least one thermal transfer device is preferably selected from the group consisting of heatable plates, cylinders, rollers, bands, mats, and foils, and the at least one heat inductor is preferably selected from the group consisting of electromagnetic induction coils and electromagnetic inductors. Preferably, the apparatus according to the invention comprises at least one thermal radiator or thermal inductor, wherein also at least one thermal transfer device can be comprised according to the invention. As a matter or course, also combinations of these means for heating are possible.

The at least one means for heating can be arranged outside as well as inside the treatment basin or the treatment liquid. However, an arrangement outside the treatment basin or the treatment liquid is preferred for reasons of protection of the means for heating. On the other hand, it can be advantageous to arrange the means for heating inside the treatment basin or the treatment liquid, e.g. to keep the distance between the means for heating and the substrate lower side to be coated as short as possible, or because an exclusive heating of the substrate surface to be coated is not possible, since the remainder of the substrate material is non-transparent for the heat or induction irradiation. Here, the usage of inductors is particularly preferred, since the treatment liquid in which the same can optionally also be embedded, is not inductively heatable, so that the temperature of the treatment liquid does not or only minimally change despite the arrangement of the means for heating inside the same. According to the invention, in the case of positioning the at least one means for heating inside the treatment basin or the treatment liquid, it must be ensured that only such means as in particular thermal inductors is or are used, whose activation essentially does not result in heating the treatment liquid over a tolerable amount, or essentially does not induce any of the undesired reactions described in the art (e.g. formation of colloids).

According to a preferred embodiment, the treatment basin is designed in such a manner that the size of the surface area of the treatment liquid that can be contacted by the substrate approximately corresponds to the size of the substrate to be coated, so that the entire surface of the substrate can be coated simultaneously. If the substrate shall be coated completely (on its entire surface) up to the edge, the basin can be at least slightly larger than the substrate width. Alternatively, the basin can be at least slightly, preferably approx. 0.8 cm, smaller than the substrate width, if the substrate shall not be treated in an accordingly wide border region.

According to a preferred embodiment of the invention the apparatus further comprises at least one inlet, through which treatment liquid preferably continuously streams into the treatment basin, as well as at least one lip, over which the treatment liquid can be drained off from the basin, and preferably be fed into a catchment tank. A different discharge rate of treatment liquid from the basin is achieved depending on the weir height of the lip. A circulator pump can preferably be used for the liquid transport. The bath depth of the treatment basin can preferably range between 1 mm and 40 mm, and can particularly preferred be adjustable. Furthermore, the bath depth can be provided wedge-shaped ascending and/or sloping in transport direction. As a result, different and according to the application advantageous flow characteristics can be generated inside the treatment basin. Furthermore, these can be influenced by an increase or decrease of the pumping capacity, so that an undesired change of the composition of the liquid in direct proximity to the substrate surface can be opposed. In the catchment tank, in or above which the treatment basin is preferably arranged, the excessive treatment liquid is collected and particularly preferred fed back again into an according circuit, so that a most possible low consumption of treatment liquid is achieved.

According to a preferred embodiment, the apparatus further comprises sensors that can record the composition and/or the temperature of the treatment liquid and, if necessary, forward the data to a subsequently arranged control device, wherein this device preferably is comprised by the apparatus, or is functionally assigned to the same. This control device compares the measured actual value with stored desired value(s) and adjusts, if necessary, the composition or temperature of the treatment liquid in such a manner that it e.g. controls the valves of a reservoir tank with cooled treatment liquid. According to a preferred embodiment, the apparatus according to the invention further comprises at least one means for mixing the treatment liquid, which is selected from the group consisting of drag flow, convection, ultrasound, and/or nozzles. For a homogenous result, it is particularly important that the composition and concentration of the treatment liquid in the treatment bath is as much as possible the same at every location of the substrate surface. If possible, the predetermined treatment liquid streaming into the treatment basin must thus be thoroughly mixed, which is preferably effected by provision of appropriate means. This possibly necessary adjustment of the concentration within the bath can e.g. be effected by temperature convection, as well as preferably e.g. by the support of ultrasonic transmitters and/or nozzles, which particularly preferred are present in an apparatus suitable according to the invention in a multitude, ensuring a homogenous distribution of the influent liquid.

According to a preferred embodiment of the apparatus according to the invention, the at least one means for supporting the substrate is provided as at least one means for the transport of the substrate during the treatment. As already mentioned for the case with no substrate transport during the treatment, this or these means is or are designed in such a manner that they position the substrate with its side to be treated facing downwards, i.e. the substrate rests on the transport means and can be transported over or through the treatment liquid. Any kind of protection of the side of the substrate that is not to be treated is not provided or necessary. If desired, the substrate can be positioned so high above the treatment liquid, that a wetting of the edges of the substrate is at least to a large extent avoided.

It is particularly preferred that the at least one transporting means suitable according to the invention is selected from the group consisting of transport rollers, transport bands, and transport belts, wherein this means preferably can provide a transport speed of the substrate of approximately 10 cm/min up to approximately 3.0 m/min, and particularly preferred of approximately 1.2 up to 1.5 m/min. A mixing of the bath liquid can be achieved or at least be supported without further accessories by the natural drag flow of the surface to be coated. In the case of a substrate that protrudes the basin edge on both sides, this substrate border can preferably serve as supporting area for the transporting means. According to a particularly preferred embodiment of the transporting means in form of a transport band, the same can also serve as sealing means for avoiding an undesired wetting of the circumferential edge and/or of the upper side of the substrate. Further, a lateral overflow of treatment liquid into the catchment tank can hereby be avoided. According to the invention, the consumption of treatment liquid can be adjusted by a preferred adaption of the weir height of the lip to changed transport speeds.

In the case of an intended continuous transport of the substrate during treatment, the treatment basin is preferably designed in such a manner that its width, i.e. its horizontal dimension perpendicular to the transport direction, approximately corresponds to the one of the substrate to be coated, so that the substrate can be coated simultaneously over its entire width. For a potentially desired untreated border area, the above explanations with regard to a treatment without transport analogously apply.

According to a preferred embodiment, the apparatus according to the invention further comprises several independently controllable means for heating the substrate as well as a control device for the separate control of the same. Thus, the separate control allows for the generation of regions in which different heat or power supply act on the substrate while it is exposed to the means for heating. The substrate passes through these regions during transport, so that every location on the substrate lower side undergoes or experiences a predetermined temperature profile according to the invention. However, it is to be ensured that the temperature profile, in a substrate's cutting plane being perpendicular to the transport direction, in particular at its lower side to be coated is to a large extent constant.

According to a preferred embodiment, the optionally sectional heating of the substrate is only effected when the same is positioned above the surface of the treatment liquid. For this, preferably at least one means for detecting the position of the substrate may be provided which serves for the targeted control of the means for heating such that only those heating means are activated under or above which the substrate is presently located. It thus can be achieved that there is no undesired heating of the uncovered bath. The means for detecting the position of the substrate are preferably selected from the group consisting of mechanical sensors, optical sensors, and those that are coupled with the transport device. Without an actual measurement the latter report the expected position of the substrate to the control, which then in turn causes for an according activation of the means for heating.

According to a preferred embodiment, the apparatus according to the invention further comprises a means for cooling of the treatment liquid. According to a preferred embodiment, the treatment liquid can be actively or passively cooled in order to counteract the above-mentioned undesired effects of heating the treatment liquid by heat transfer from the substrate surface. Cooling fins that are designed to be flown through by the treatment liquid can e.g. be provided for passive cooling. However, their efficiency depends on the ambient temperature and is therefore limited, in particular at low temperature differences. Thus, active cooling should be preferred, by which larger heat quantities can be drawn from the treatment liquid by means of heat exchangers that e.g. can be electrically operated. It is particularly preferred that these heat exchangers are arranged in such a manner within the liquid circuit that the liquid flowing out of the treatment basin runs through the heat exchanger before it is fed back into the basin. Most preferably, the fed back, now cooled liquid firstly enters a mixing tank in which, if necessary, a reconditioning of the desired composition is effected, so that the treatment basin can be supplied with a well-tempered and fresh treatment liquid.

In order to achieve a most possible uniform effect of the means for heating onto the substrate, the apparatus according to the invention can, according to another preferred embodiment, further comprise also a pre-heating device which heats the substrate to a defined temperature prior to the actual coating process. By this, e.g. influences of different ambient temperatures can be compensated to a large extent. The pre-heating temperature is preferably adjusted in such a manner that it corresponds to the optimal starting temperature of the coating process mentioned above.

The apparatus according to the invention can further comprise a pre-cleaning device enabling to implement a cleaning step e.g. for filter cleaning prior to the actual coating process and the optional pre-heating step, if this is necessary.

After the coating, possibly present excessive treatment liquid can be removed from the substrate surface by means of a liquid removing device such as e.g. an air stream which is optionally comprised by the apparatus.

The apparatus can further comprise a rinsing and/or drying device, by which the previously described process steps are followed by a rinsing and/or drying step of the substrate.

Eventually, the apparatus according to the invention can further comprise one or several turnover devices for performing turnover steps, if the substrate is firstly delivered to the coating with the side to be coated facing upwards and/or shall be transferred into this orientation after the coating. The apparatus which is used for this purpose must enable a rapid, safe and damage-free turnover of the substrate.

The method and the apparatus according to the invention were illustrated with regard to the single-sided wet chemical coating of flat substrates. It is, however, clear that the method as well as the apparatus according to the invention can generally be used for the single-sided wet chemical surface modification of flat substrates without changing the essential characteristics of the invention.

### DESCRIPTION OF THE FIGURE

FIG. 1 schematically depicts the main characteristics of the apparatus 1 according to the invention for the single-sided wet chemical surface modification as in particular the coating of flat substrates.

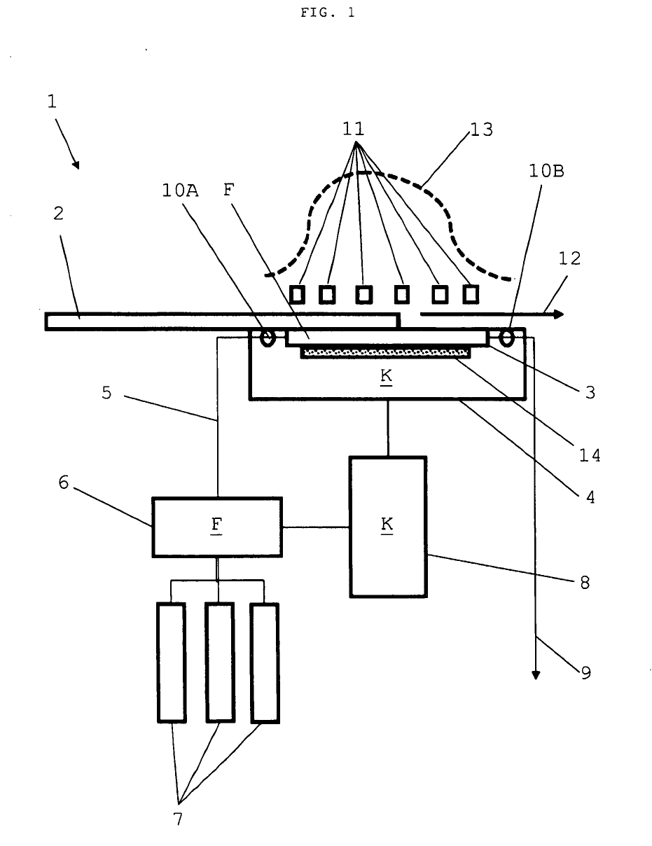

This FIGURE shows a flat substrate 2 which partially is located above a treatment basin 3. The treatment basin 3 is filled with treatment liquid F. Furthermore, the treatment basin 3 is arranged in a cooling basin 4. The cooling basin 4 is filled with a cooling liquid K which ensures that the temperature in the treatment basin 3 corresponds to a desired temperature in that it takes up and removes heat from the treatment basin 3. The treatment basin 3 is connected to a mixing tank 6 by means of according ducts 5 which are depicted as thin lines in the FIGURE. This mixing tank is fed by several reservoirs 7, in which the components of the treatment liquid F are present. The cooling liquid K is kept at a desired cooling temperature by a means for cooling 8 with which it is fluidically connected. Also fluidically connected are the means for cooling 8 and the mixing tank 6, thus enabling a tempering of the fresh treatment liquid F being present in the mixing tank 6. Excessive or consumed treatment liquid F can flow out from the treatment basin 3 via a drain 9.

The height of the level of the treatment liquid can be adjusted by means of a weir which is arranged at the inlet 10A at the outlet being in the form of a lip 10b of the treatment basin 3.

Means for heating 11 are arranged above the treatment basin 3 and therefore above the substrate 2. The electrical wires etc. which are necessary for operation of the same are not shown for reasons of clarity which also applies to preferably present control or regulation devices etc., as well as to pumps that are necessary for the delivery of the treatment liquid F or the cooling liquid K.

Upon movement of the substrate 2 in transport direction 12 the same is heated from its upper side that is not to be coated. By this, a temperature profile 13 which is depicted as a dashed line develops depending on the exposure duration and the level of the irradiated power. Preferably, the temperature profile is constant over the entire width of the substrate 2, wherein the substrate width extends perpendicular to the plane of projection.

For a better mixing of the treatment liquid F during the substrate's 2 passage as well as for the removal of possible undesired near-surface parts of the treatment liquid F being heated by the substrate, a means for mixing 14 which, in the FIGURE, is provided as ultrasonic transducer is arranged below the treatment basin 3.

### LIST OF REFERENCES

1 apparatus
2 substrate
3 treatment basin
4 cooling basin
5 ducts
6 mixing tank
7 reservoir
8 means for cooling
9 drain
10A inlet
10B lip
11 means for heating
12 transport direction
13 temperature profile
14 means for mixing
F treatment liquid, liquid
K cooling liquid

1. Method for the single-sided wet chemical surface modification as in particular the coating of a flat substrate (2) by using a liquid (F) being present in a treatment basin (3), the liquid's chemical constituents being precipitable by suitable temperature control onto the substrate surface under formation of a permanent layer, wherein the heating of the to be coated substrate lower side to be coated which is necessary for the formation of the desired layer is not effected by the treatment liquid, but by at least one suitable means for heating (11) that is capable of heating the substrate (2) to the necessary temperature, without the upper side that is not to be treated being wetted during treatment with a heating liquid, and without the substrate (2) being held from above or protected.

2. Method according to claim 1, wherein the substrate (2) comprises glass, metal, and/or plastic, and the coating is performed in the course of the production of thin film solar cells or modules, and wherein the treatment liquid (F) comprises cadmium or zinc sulphate or acetate, respectively.

3. Method according to claim 1, wherein the composition and/or the temperature of the treatment liquid (F) are continuously monitored, and readjusted if required.

4. Method according to claim 1, wherein during treatment the substrate (2) with its lower side to be treated rests on a transport means, and is continuously transported over or through the liquid (F).

5. Method according to claim 1, wherein several means for heating (11) the substrate (2) are used, whose power can be controlled independently of each other.

6. Method according to claim 1, wherein the lower side of the substrate during its coating is uniformly heated to different temperatures.

7. Method according to claim 5, wherein the means for heating (11) are controlled independently of each other in such a manner that the substrate's lower side to be coated undergoes or experiences in transport direction (12) a predetermined temperature profile (13) during its transport over or through the liquid (F).

8. Method according to claim 7, wherein the temperature profile (13), in a substrate's (2) cutting plane being perpendicular to the transport direction (12) is to a large extent constant.

9. Method according to claim 1, wherein the means for heating (11) of the substrate (2) is/are selected from the group consisting of thermal radiators, thermal transfer devices, thermal inductors, and combinations thereof.

10. Method according to claim 9, wherein the thermal radiator(s) is/are selected from the group consisting of long-wave infrared radiators, infrared lasers, and microwave devices.

11. Method according to claim 9, wherein the thermal transfer device(s) is/are selected from the group consisting of heatable plates, cylinders, rollers, bands, mats, and foils.

12. Method according to claim 9, wherein the thermal inductor(s) is/are selected from the group consisting of induction coils and inductors.

13. Apparatus (1) for the single-sided wet chemical surface modification as in particular the coating of a flat substrate (2), at least comprising a treatment basin (3) for reception of treatment liquid (F), at least one suitable means for heating (11) the substrate lower side to be coated to the temperature that is necessary for the formation of the desired layer, as well as at least one means for supporting and positioning the substrate with its side to be treated facing downwards, wherein the apparatus (1) does not comprise any means by which the substrate can be held from above or protected.

14. Apparatus according to claim 13, in which the size of the surface area of the treatment liquid (F) that can be contacted by the substrate (2) approximately corresponds to the size of the substrate (2).

15. Apparatus according to claim 13, further comprising at least one inlet (10A), through which the treatment liquid (F) streams into the treatment basin (3), as well as at least one lip (10B), over which the treatment liquid (F) flows off the treatment basin (3).

16. Apparatus (1) according to claim 13, further comprising at least one means for mixing (14) the treatment liquid (F), being selected from the group consisting of drag flow, convection, ultrasound, and/or nozzles.

17. Apparatus (1) according to claim 13, in which the at least one means for supporting the substrate (2) is provided as at least one means for the transport of the substrate during treatment, so that the substrate (2) with its side to be treated facing downwards can be transported over or through the treatment liquid (F).

18. Apparatus (1) according to claim 17, in which the at least one means for the transport is selected from the group consisting of transport rollers, transport bands, and transport belts, wherein this means preferably can provide a transport speed of the substrate (2) of approximately 10 cm/min up to approximately 3.0 m/min, and particularly preferred of approximately 1.2 up to 1.5 m/min.

19. Apparatus (1) according to claim 13, further comprising several independently controllable means for heating (11) the substrate (2), as well as a control device for the separate control of the same.

20. Apparatus (1) according to claim 13, further comprising at least one means for detecting the position of the substrate.

21. Apparatus (1) according to claim 13, further comprising a means for cooling (8) of the treatment liquid (F).

22. Apparatus (1) according to claim 13, further comprising a pre-heating device and/or a pre-cleaning device.

23. Apparatus (1) according to claim 13, further comprising a rinsing and/or drying device.

24. Apparatus (1) according to claim 13, further comprising one or several turnover devices.
